(19) United States
(12) Patent Application Publication
(10) Pub. No.: US 2026/0293619 A1
(43) Pub. Date: Sep. 24, 2026

(54) BOW COMPENSATION OF SEMICONDUCTOR SUBSTRATE USING PLASMA JET

(71) Applicant: Lam Research Corporation, Fremont, CA (US)

(72) Inventors: Michael Wood, West Linn, OR (US); Karl Frederick Leeser, West Linn, OR (US)

(21) Appl. No.: 19/474,074

(22) PCT Filed: Mar. 29, 2024
(86) PCT No.: PCT/US2024/022362

§ 371 Date: Oct. 9, 2025

Related U.S. Application Data
(60) Provisional application No. 63/495,284, filed on Apr. 10, 2023.

(51) Int. Cl. H10P 90/00; H05H 1/26; H10W 42/00

(52) U.S. Cl. CPC H10P 90/124; H05H 1/26; H10W 42/121; H05H 2245/40

(57) ABSTRACT

Methods and apparatus are provided for bow compensation of a semiconductor substrate or wafer using a plasma jet. In some embodiments, the apparatus may be for surface modification of a backside of a substrate, the substrate having a frontside, the frontside having electronic device features fabricated thereon. The apparatus may include, among other components, a nozzle configured to direct a plasma jet onto the backside of the substrate and thereby deposit a material on the backside of the substrate, wherein the backside layer comprises the material; an actuator (e.g., a chuck) configured to adjustably position the backside of the substrate with respect to the nozzle during deposition of the backside layer; and a controller configured to cause the plasma jet to deposit the backside layer on the backside of the substrate in a manner such that the backside layer has different properties varying at different locations of the backside layer.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Semiconductor manufacturing processes involve many deposition and etching operations, which can cause bow and warpage in a semiconductor substrate (e.g., wafer). For example, as layers of films are stacked on top of each other during fabrication, and as deposited layers build up on the front side of the substrate, more stress is introduced to the substrate. A sufficiently large net compressive or tensile stress can cause the substrate to bow, in which a deviation occurs from a plane of the substrate ( e.g., an average midplane of the substrate). Semiconductor substrates can be highly sensitive to such deviations. It is desirable to mitigate substrate deformation or bow during the manufacturing process.

Background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

In one aspect of the present disclosure, an apparatus for surface modification of a backside of a substrate is disclosed. In some embodiments, the substrate may have a frontside, the frontside having electronic device features fabricated thereon, and the apparatus may include: a nozzle configured to direct a plasma jet onto the backside of the substrate and thereby deposit a material on the backside of the substrate and form a backside layer comprising the material; and actuator configured to adjustably position the backside of the substrate with respect to the nozzle during deposition of the material; and a controller configured to cause the plasma jet to deposit the material on the backside of the substrate in a manner such that the formed backside layer has different properties varying at different locations of the backside layer.

In another aspect of the present disclosure, a method of depositing a backside layer on a backside of a substrate is disclosed. In some embodiments, the substrate may have a frontside, the frontside having electronic device features fabricated thereon, and the method may include: depositing a material at a first location of the backside of the substrate, wherein the backside layer comprises the material, wherein the backside layer at the first location has a first value of a property, wherein the material is deposited at the first location by a plasma jet emitted from a nozzle located proximate the first location; moving the nozzle and/or the substrate to position the nozzle to be proximate a second location of the backside of the substrate; and while the nozzle is proximate the second location, depositing the material at the second location, wherein the backside layer at the second location has a second value of the property, which is different from the first value of the property.

These and other features of the disclosed embodiments will be described in detail below with reference to the associated drawings.

### BRIEF DESCRIPTION OF DRAWINGS

FIG. 1A is an example cross-sectional view of a substrate with a frontside layer and a backside layer.

FIGS. 1B and 1C illustrate simplified cross-sectional views of a substrate without any bowing and with bowing.

FIG. 2 is a simplified block diagram of a system configured to provide a pressurized jet of plasma radicals toward a backside of a semiconductor substrate, according to some embodiments.

FIG. 2A illustrates an expanded, vertical cross-sectional view of the nozzle used in the system of FIG. 2, in some implementations.

FIG. 2B an example view of the plasma radicals with the shield gas directed toward an edge of the substrate, according to some implementations of the system of FIG. 2.

FIG. 3 is a simplified block diagram of another system configured to provide a pressurized jet of plasma radicals toward a backside of a semiconductor substrate, according to some embodiments.

FIG. 3A illustrates an example cross-sectional view of the substrate that may be processed using the system of FIG. 3.

FIG. 3B is a top-down view of the substrate depicted in FIG. 3A.

FIGS. 4A-4D are illustrative example patterns of deposition or etch using the system of FIG. 2 or FIG. 3.

FIG. 5 is a flow diagram illustrating a method for depositing a backside layer on a backside of a substrate, according to some embodiments.

FIG. 6 illustrates a simplified block diagram of a system or apparatus as described herein.

### DETAILED DESCRIPTION

The following terms are used throughout the present specification:

“Manufacturing equipment” refers to equipment in which a manufacturing process takes place. Manufacturing equipment often has a process chamber in which the workpiece resides during processing. Typically, when in use, manufacturing equipment performs one or more semiconductor device fabrication operations. Examples of manufacturing equipment for semiconductor device fabrication include deposition reactors such as electroplating cells, physical vapor deposition reactors, chemical vapor deposition reactors, and atomic layer deposition reactors, and subtractive process reactors such as dry etch reactors (e.g., chemical and/or physical etch reactors), wet etch reactors, and ashers. In some embodiments, the manufacturing equipment may be a multi-station process chamber having, e.g., four stations.

As referred to herein, manufacturing equipment is sometimes simply referred to as a “process chamber.” In various embodiments, a process chamber is typically a sealed enclosure in which a substrate is immobilized during processing. The process chamber may include components associated with delivery of and removal of gases. It may also include components associated with generating a plasma and controlling properties of the plasma within the chamber. It may include components for controlling the pressure, including pulling a vacuum within the chamber. In the context of this disclosure, the process chamber may include a pedestal on which the substrate sits while it is being processed. A pedestal may be outfitted with a chuck such as an electrostatic chuck to hold the substrate in position during processing.

A “semiconductor device fabrication operation” as used herein is an operation performed during fabrication of semiconductor devices. As referred to herein, such a fabrication operation is sometimes simply referred to as a “process” or as “processing.” Examples of processing include deposition of a material on a substrate, selectively etching material from a substrate, and ashing of photoresist on a substrate. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition). In the context of etch processes, a substrate etch process includes processes that etch a mask layer or, more generally, processes that etch any layer of material previously deposited on and/or otherwise residing on a substrate surface. Such an etch process may etch a stack of layers in the substrate.

The terms “semiconductor wafer,” “wafer,” “semiconductor substrate,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, or 300 mm, or 450 mm. Examples of semiconductor substrate materials include silicon (Si), gallium arsenide (GaAs), and silicon germanium (SiGe).

Besides semiconductor substrates, other workpieces that may take advantage of the disclosed embodiments include various articles such as magnetic recording media, magnetic recording sensors, mirrors, optical elements, display devices or components such as backplanes for pixelated display devices, flat-panel displays, micro-mechanical devices and the like. The workpiece may be of various shapes, sizes, and materials.

“Wafer bow” or “substrate bow” as used herein may refer to a deformation of a substrate or wafer. The deformation may have radial and/or azimuthal components. Examples of types of wafer bow include dome shapes, dish shapes, and potato chip shapes. Wafer bow may occur during fabrication, for example, as a result of stress to the wafer during deposition of materials on an active surface of a wafer substrate. Wafer bow may occur during various types of fabrication, such as when large stacks of materials are deposited. Wafer bow may cause complications in subsequent processing steps. For example, the wafer may fail to chuck correctly if an amount of bowing is too large. Moreover, some processing steps (e.g., photolithography) may produce poor results if performed on a wafer that is excessively bowed.

Wafer bow may be measured as a deviation of the mean or median distance of the surface of the wafer to a reference plane. The point of the median surface of the wafer may be the center point (e.g., in the case of concave or domed bowing), or an edge point of the wafer and/or an average edge point of the wafer (e.g., in the case of warping or convex bowing).

This disclosure relates to compensation of bowing or other deviations of a semiconductor substrate. Semiconductor fabrication processes involve formation of various structures, e.g., on a front side of the substrate, which can cause bowing. Bowing is a salient concern in semiconductor fabrication, and can be measured in different ways, such as using an optical technique. Bowing of a semiconductor substrate can also be measured or evaluated by obtaining a wafer map. Bowing can be quantified using a bow value or warpage value, which is measured as the vertical distance between the lowest point of the semiconductor substrate to the highest point on the substrate. The warpage value can be along an axis. For example, an asymmetrically warped substrate may have an x-axis warpage and a y-axis warpage.

Different types of bowing exist. In a bow-shaped substrate, the lowest point is the center of the substrate and the highest point is the edge of the substrate. In a dome-shaped substrate, the lowest point is the edge of the substrate and the highest point is the center of the substrate. Bow-shaped and dome-shaped substrates have symmetrical or uniform bowing. Substrates can also have asymmetric bowing. In asymmetric bowing, warpage is measured along an x-axis and a y-axis. An asymmetrically bowed substrate has different values for the x-axis warpage and y-axis warpage. In some cases, an asymmetrically bowed substrate has a negative x-axis warpage and a positive y-axis warpage. In some cases, an asymmetrically bowed substrate has a positive x-axis warpage and a negative y-axis warpage. In some cases, an asymmetrically bowed substrate has both a positive x-axis warpage and a positive y-axis warpage, but the warpage values are different. In some cases, an asymmetrically bowed substrate has both a negative x-axis warpage and a negative y-axis warpage, but the warpage values are different. One example of an asymmetrically bowed substrate is a saddle-shaped substrate. For a saddle-shaped substrate, in one example, the warpage on the x-axis may be 200 μm and the warpage on the y-axis may be −200 μm. Saddle-shaped substrates have two opposing edges of the substrate that are curved upward while another two opposing edges of the substrate are curved downward.

Bowing can cause problems with subsequent processing, such as during lithography, as etching can be uneven if the semiconductor substrate is warped. Another potential problem is that the substrate may fail to chuck correctly if the bowing is too great. High bowing can be caused by, for example, deposition of thick, high stress carbon hard mask layer. Additionally, due to multi-stacked films and the presence of thick, high stress carbon-based hard masks used in such fabrication processes, etching can cause some asymmetric warpage and deposition processes can introduce significant substrate warpage of up to a variation of between ±500 μm to −1300 μm bow. For example, an ashable hard mask may have a stress of up to −1000 MPa and have introduce a bow value of up to −1000 μm. Addressing such substrate warpage can be a challenge as subsequent processing may be affected by a substrate warpage exceeding +500 μm, and can be a particular challenge, especially when substrates are used in subsequent processing involve chucking of the substrate to an electrostatic chuck, as many electrostatic chucks have a “chucking limit,” which is defined as the maximum warpage tolerated before the substrate cannot be effectively chucked. Many electrostatic chucks have a chucking limit of about +300 μm. As a result, highly warped semiconductor substrates may not be processed in some tools. Additionally, processing of highly warped semiconductor substrates may cause further warping. For example, etching of a trench in one direction can cause warping in asymmetric bowing due to asymmetric stress on the semiconductor substrate.

The semiconductor industry has embraced deliberate backside deposition of thin films to compensate for wafer bow induced due to high stress frontside films. Various approaches may be used. As one example, plasma-enhanced chemical vapor deposition (PECVD) technology can be used to deposit a film across the entire substrate backside. An alternative example approach used in the industry is the use of a backside film deposited by physical vapor deposition (PVD) technology.

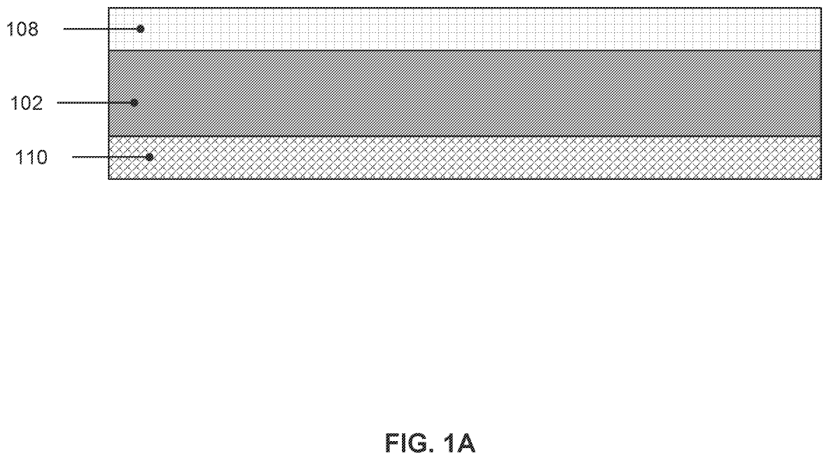

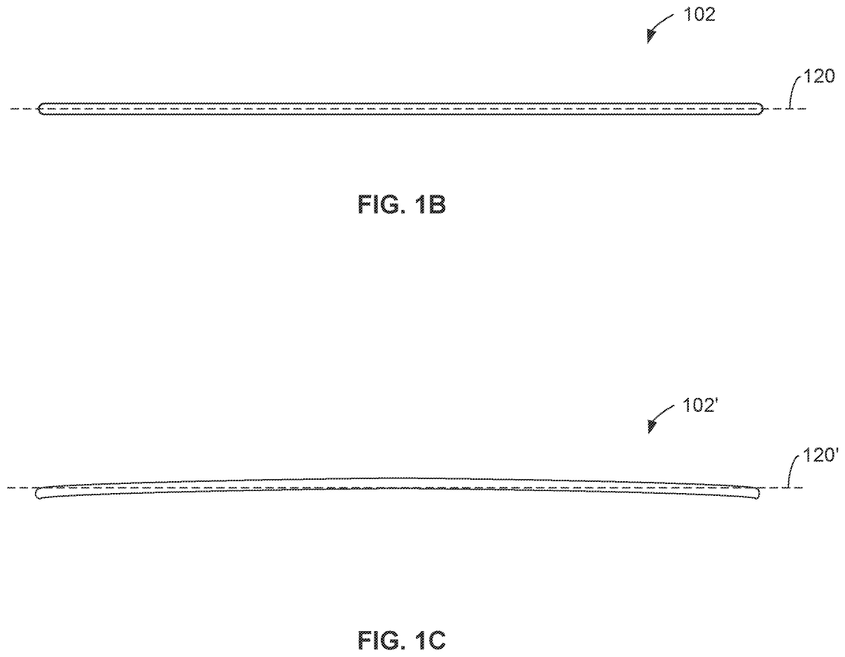

Generally speaking, backside deposition may form a dielectric film on the backside of the a substrate or wafer. FIG. 1A is an example cross-sectional view of a semiconductor substrate 102 (e.g., a wafer) with a frontside layer 108 and a backside layer 110. If the backside layer 110 has opposite internal stress and of comparable magnitude to the internal stress created on the frontside, the backside film effectively counteracts and corrects the bow. A typical scenario might involve the following:
1. Deposit one or more frontside layers with high internal stress that produce significant bowing (e.g., in chamber A).
2. Deposit a backside layer having internal stress that counteracts the internal stress of the one or more frontside layers and reduces or eliminates the bowing (e.g., in chamber B).
3. Pattern the frontside of the unbowed substrate by photolithography.
4. Etch the unbowed, patterned substrate (e.g., chamber C).

Chambers A, B, and C may each be different, although this is not always the case. For example, in some embodiments, chambers A and C are the same.

For uniform bow, the aforementioned approaches are acceptable, but a growing area of interest is compensation for bow of a semiconductor substrate which is saddle-shaped, as few techniques exist for compensating for asymmetric warpage of a substrate such as saddle-shaped bowing. Applying a uniform backside layer (where bow-compensating effect of a backside layer is the same everywhere on the substrate) to a saddle-shaped substrate will not produce a planar substrate. Due to different amounts of bowing on different axes, some of the substrate will remain warped after uniform bow compensation. An enhanced approach to compensating for saddle-shaped bowing that may be more cost effective and flexible is desirable.

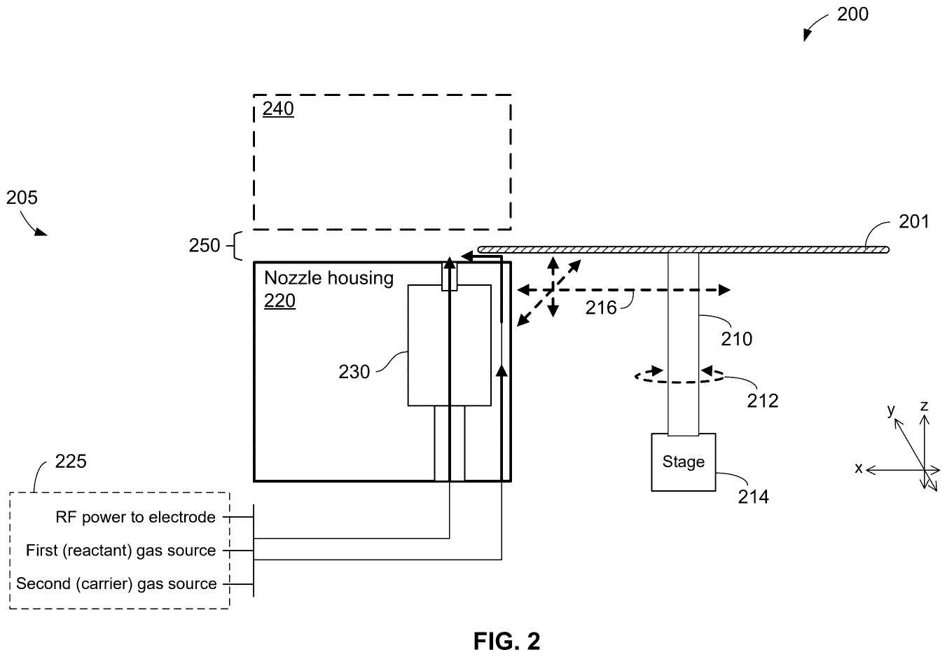

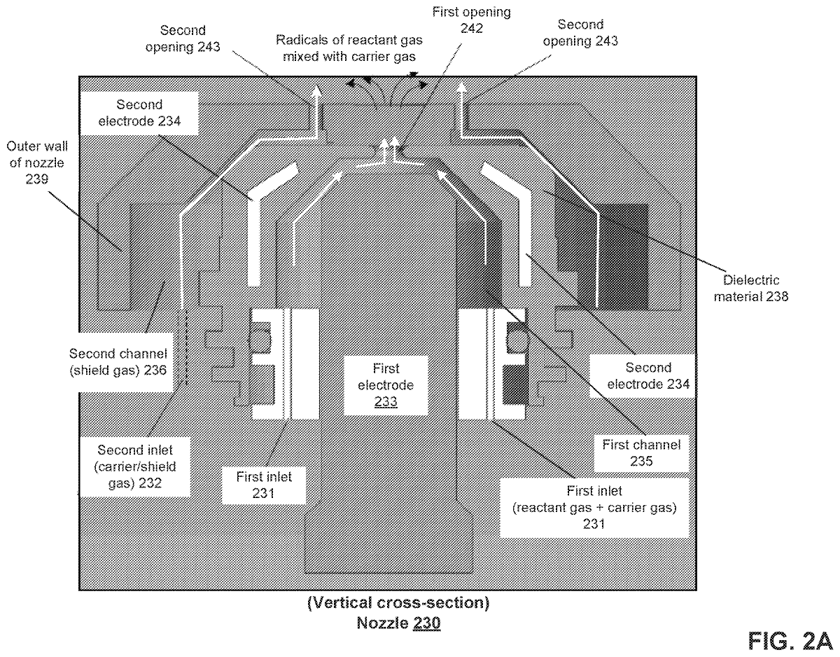

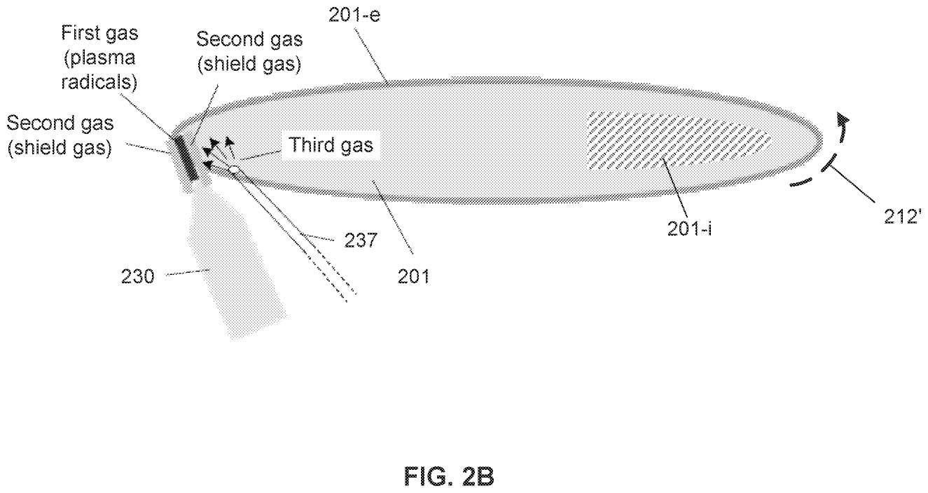

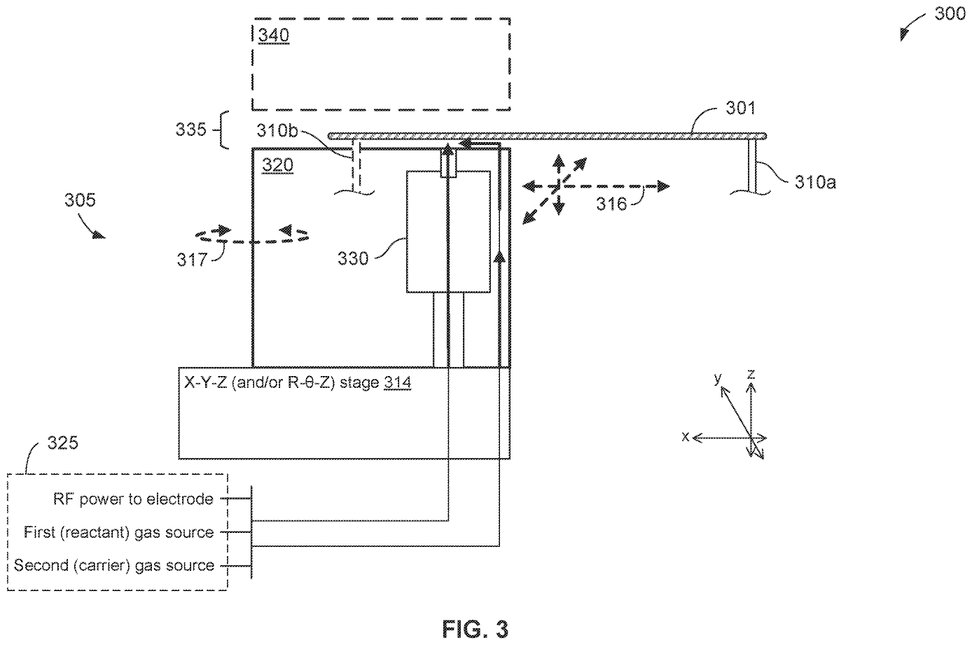

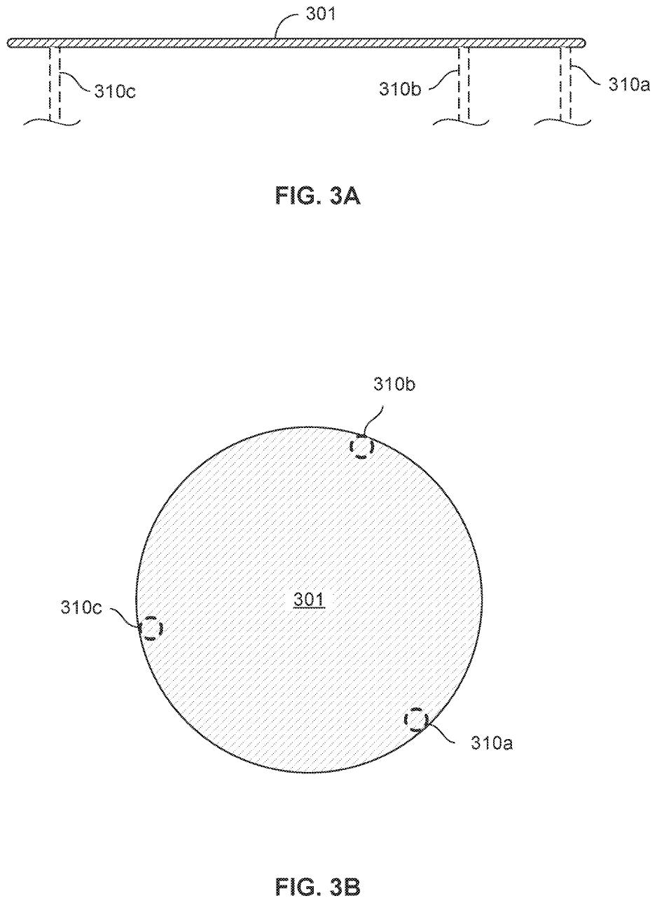

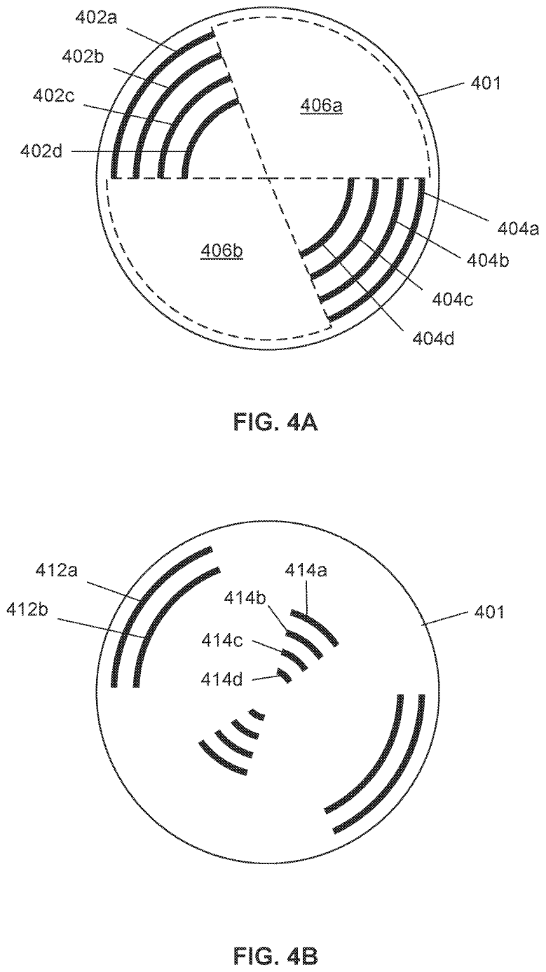

Such an enhanced approach, according to some embodiments of the present disclosure, may leverage so-called atmospheric pressure plasma jet (APPJ) technology to produce a nonuniform backside layer, which in some implementations may involve operating one or more nozzles at atmospheric conditions to provide a pressurized jet of plasma radicals toward a semiconductor substrate. The details of the components of a system using APPJ will be discussed with reference to FIGS. 2, 2A, 2B and 3. Such nonuniform backside layer may have varying bow composition strength over the backside surface of the substrate, and the bow-compensating effect may vary in the azimuthal and/or radial direction. APPJ may be extended to recipe-controlled, backside deposition applications. In APPJ hardware, a substrate may be spun on a near-atmospheric pressure aligner hardware and through a controlled plasma jet region. The nonuniformity in the backside layer may be produced using a plasma jet configured to deposit and/or etch backside layer material selectively at different positions on the backside of a substrate. Plasma chemistry may etch the region near the substrate edge (or other portions of the substrate). Alternatively, rather than etch, a suitable choice of plasma feed gases can induce a plasma enhanced chemical vapor deposition of material. In some embodiments of the present disclosure, rather than using a single jet, a pie-shaped jet that may consist of a single jet region or an array of jets may be employed. In some implementations, such an array may be as simple as many jets distributed across the substrate radius.

The resulting bow compensating effect is illustrated in FIGS. 1B and 1C. FIG. 1B shows a simplified cross-sectional view of a substrate 102 without any bowing. The substrate 102 may be associated with a midplane (or average midplane) 120, which may be a plane passing through the substrate 102 at a midpoint distance between the highest point of the substrate and the lowest point of the substrate. In FIG. 1B, the midplane 120 passes through the substrate 102 in such a way as to divide the substrate 102 into symmetrical vertical halves. FIG. 1C shows a simplified cross-sectional view of a substrate 102′ with bowing. Notably, the substrate 102′ is depicted as being slightly curved, which may be exaggerated or not to scale for illustrative purposes. Internal stress from such prior processing may cause the bowing, and it is desirable to mitigate the bow. Such bowing may have been the result of prior processing, such as frontside deposition or inadvertent or unintentional backside deposition. The substrate 102′ with bow may be associated with a midplane (or average midplane) 120′, which does not pass through the exact middle of the substrate 102.

One advantage of using APPJ is that, although the substrate rotation may be fast (a rate of rotation of, e.g., 60-120 rotations per minute), modulating the RF (radio frequency) power to plasma jets can be done much faster. Synchronization of the power and substrate angle or substrate position can produce regions of various film properties to tune the net substrate shape to a desired, nominally flat (or at least flatter) profile, thereby mitigating bow. Between these two broad variables, a direct-write process may be implemented, wherein for a saddle-shaped substrate, different properties are deposited in alternating quadrants, for example (even quadrants versus odd quadrants). Two example film properties to modulate include film thickness and stress.

Thus, the disclosed concept offers the benefits of direct-write capability for high process tunability, very high throughput due to very high deposition rate at near atmospheric pressure, much lower cost, the ability to easily integrate with deposition or etch tools, and if pursued as a standalone implementation, a much lower product footprint.

### Atmospheric Pressure Plasma Jet System

FIG. 2 illustrates a simplified block diagram of a system 200 configured to provide a pressurized jet of plasma radicals toward a backside of a semiconductor substrate 201, according to some embodiments. The system 200, in some embodiments, may include a single nozzle 230 that is at least partially housed within a nozzle housing 220 of an assembly 205 that may integrate other components 225 along with the nozzle housing 220. In some embodiments, the nozzle housing 220 can be extended to include more than one nozzle (e.g., up to 5 to 10 nozzles). In such cases, each of the multiple nozzles may be capable of either etching or depositing; e.g., a first nozzle may be used for depositing, and a second nozzle may be used for etching. Typically, all the nozzles will provide an etchant or all will provide a deposition precursor. The system 200 may be operated at atmospheric conditions. The system 200 incorporating the nozzle 230 allows for minimal hardware changes while significantly improving the deposition or etch rate with respect to the substrate 201.

In some embodiments, a radio frequency (RF) power source may be coupled to the nozzle 230 so as to provide RF power to electrodes (e.g., a first electrode and a second electrode) that may be housed within the nozzle 230 or the nozzle housing 220. The RF power source and/or one or more gas sources (e.g., a first gas source and a second gas source) may be connected to the nozzle housing 220, the nozzle(s) 230, and/or components of the assembly 205 or components of the nozzle housing 220 (e.g., electrodes) via an electrical line and/or a gas line. In some implementations, the RF power source may be coupled to the nozzle 230 and configured to provide RF power to generate plasma of the first gas (e.g., in a first channel defined between the first electrode and the second electrode, as will be described in more detail below). Specifically, in some applications, the nozzle 230 may emit radicals of the plasma generated within the nozzle 230 and carried by a second gas (e.g., carrier gas). The RF power may be used to generate radicals of plasma of the first gas in a first channel (to be described in greater detail below). The radicals may then be carried out of the first channel through a first opening (i.e., first outlet) defined at an opening of the nozzle 230. The second gas may flow out of a second channel through a second opening (i.e., second outlet) defined at the opening of the nozzle 230. The second opening may be disposed adjacent to the first opening so that the second gas flowing out of the second channel surrounds the radicals of plasma flowing out of the first opening to create a pressurized jet flow of plasma radicals so as to enhance the deposition or etch rate. The second gas may act as a shield to enable a focused application of the radicals to a specific location (e.g., the edge) of the substrate 201 received above the nozzle 230. Further, the second gas shield may prevent recombination and other reactions from occurring in the air and to prevent plasma radicals from dispersing.

As noted above, the RF power may be modulated so as to vary the emission of plasma radicals as the substrate 201 spins, thereby creating a desired pattern of deposition or etching, e.g., at the backside of the substrate 201. Such modulation may be performed based on signals generated by a controller, logic, a differential drive, etc. that is coupled to the nozzle 230.

As mentioned or will be mentioned elsewhere herein, the controller or logic may further control one or any combination of the following parameters: rate of rotation of the substrate, nozzle position relative to the substrate (in, e.g., x, y and/or z-axis), and deposition rate parameters (such as plasma power, plasma frequency, gas flow rate, gas composition, and/or gas pressure).

Parameters may influence the manner of deposition as well. Such deposition parameters may include: plasma power (on/off; or high/low between high and low RF power, rather than on to off), plasma frequency, gas flow rate, gas composition, gas pressure, residence time of a nozzle's jet emission at any location on the substrate. Any of these deposition parameters can impact the local thickness and/or internal stress of the backside layer. These parameters may be controlled while the substrate is rotated or where the nozzle 230 is positioned with respect to the substrate (including in the X-Y-Z space, radially, and azimuthally). In implementations where multiple nozzles 230 are used or included in the nozzle housing 220, each of the multiple nozzles may be separately controlled.

In some embodiments, the system 200 may further include a chuck 210 or be configured to interact with the chuck 210. In some embodiments, the chuck 210 may comprise a stem portion and a chucking portion that interfaces with the substrate 201. The stem portion may be sufficiently narrow (e.g., diameter of stem portion is significantly smaller than, e.g., less than half of, diameter of substrate 201) to accommodate movement of the chuck 210 toward the nozzle housing 220 such that the nozzle(s) 230 may have access to a majority of the surface area of the backside of the substrate 201. Those of ordinary skill in the art will recognize various configurations of securing the substrate 201 with respect to the chuck 210.

In some embodiments, the chuck 210 may be a vacuum chuck. The vacuum chuck may securely hold the semiconductor substrate 201 (e.g., a wafer) with sufficient holding force. In some embodiments, the chuck 210 may be an electrostatic chuck (ESC), which may securely hold the substrate 201 using electrostatic force. In some cases, such an ESC may be a bipolar ESC having a pair of complementary and coplanar clamping electrodes (which may be embedded within a pedestal structure) which generate the electrostatic force. In some cases, the ESC may be a monopolar ESC having one clamping electrode, where the one electrode may have a voltage applied thereto and an opposite charge may be induced in the substrate 201 using, e.g., an opposing electrode (not shown) above the substrate 201 or a plasma generated above the substrate 201.

In some embodiments, the chuck 210 may be configured to move in multiple degrees of freedom. The chuck 210 may be configured to translate along an x-axis, a y-axis and/or a z-axis, e.g., using an actuator, causing the substrate 201 to move in the corresponding direction(s). In addition, the chuck 210 may be configured to rotate 212 with respect to the z-axis, causing the secured substrate 201 to rotate at the same rate of rotation (e.g., 60-120 rotations per minute). In some implementations, the chuck 210 may be secured to a separate stage 214 (or separate actuator), e.g., an X-Y-Z stage (not shown) that is configured to translate (along the x-axis, the y-axis and/or the z-axis) and/or rotate (with respect to the z-axis), or cause the chuck 210 to translate and/or rotate. Spin about the z-axis may allow the nozzle 230 to cover the entirety of the circumference of the substrate 201, and with control of the state of the nozzle 230 (high/low or on/off), various deposition or etching patterns can be formed. As an illustrative example, the chuck 210 can move along an axis 216 toward or away from the assembly 205 or the nozzle housing 220. While the chuck 210 and/or the stage 214 in these embodiments are movable units, the assembly 205 may be stationary. However, in certain embodiments, the assembly 205 may alternatively or additionally be movable in at least one degree of freedom (e.g., along the x-axis, y-axis, and/or z-axis). That is, according to different implementations, the chuck 210 and at least a portion of assembly 205 may be stationary or movable so as to bring the nozzle 230 over the substrate 201 received on the chuck 210. In some implementations, the nozzle housing 220 or the nozzle 230 may be configured to rotate or tilt or angle about the x and/or y-axes so that the nozzle 230 can cover a greater portion of the substrate when the substrate 201 is positioned over the nozzle 230. In some implementations, the position of the nozzle 230 may be varied with respect to the nozzle housing 220. For example, the nozzle 230 may be repositioned along the x-axis, y-axis, z-axis, radial (r) direction, and/or an angular (θ) direction. Angular repositioning may cause tilting of the nozzle 230 with respect to the nozzle housing 220, but the nozzle housing 220 may remain in the same angular position or tilt.

In some example operations, the chuck 210 with the substrate 201 received thereon may be moved along an x-axis and/or y-axis (e.g., via signals from a controller (not shown)) to bring the edge or an inner portion of the substrate 201 above the nozzle(s) 230 of the nozzle housing 220. In some implementations, the assembly 205 may further include a second housing 240 or other structure opposing the nozzle housing 220. In some implementations, the second housing 240 may be stationary. In some implementations, the second housing 240 may be movable, e.g., along the z-axis. A gap 235 may thereby be created between the nozzle housing 220 and the second housing 240 to accommodate and received a portion of the substrate 201. The size of such a gap 235 may be defined so that no part of the substrate 201, when received in the gap 235, touches any surface of either the nozzle housing 220 or the second housing 240 of the assembly 205, thereby allowing the substrate 201 to rotate 212 freely to expose different portions of the substrate edge or inner portion of the substrate 201 to a focused application of plasma radicals. In some implementations, the gap 235 between the nozzle housing 220 and the second housing 240 may be defined to be between about 0.8 mm and about 2 mm during operation. In some implementations, the gap 235 may be defined to be smaller, e.g., about 0.1, 0.2, 0.3 or more mm but under about 0.8 mm. In any case, the gap 235 may be set to or adjusted (e.g., via z-axis movement of the nozzle housing 220 or the second housing 240) so that even a bowed substrate (e.g., 102′ of FIG. 1C) may be received without touching the surface of the nozzle housing 220 or the second housing 240. In some implementations, the nozzle housing 220 and/or the second housing 240 may be coupled to a sidewall and/or bottom of a process chamber associated with the system 200. In some implementations, a portion of each of the nozzle housing 220 and/or the second housing 240 may be attached to the sidewall of the process chamber of the system 200 and a remaining portion of the nozzle housing 220 and/or the second housing 240 may be designed to move along x, y, and/or z-axes so that the nozzle housing 220 with the nozzle(s) 230 can be moved to desired position(s) to position the nozzle(s) 230 below the substrate 201.

In some implementations, a plasma jet or plasma jet emitter of the nozzle 230 may be rasterized over the surface of the substrate 201. Multiple nozzles 230 (e.g., an array or group of 2-10 nozzles or plasma jets) may perform the rasterization. In some variants, the multiple nozzles 230 may be in a fixed position with respect to one another, and in some cases, multiple plasma jet emitters may be disposed within a given nozzle.

In some implementations, the system 200 may include an exhaust (not shown) to promptly remove plasma radicals and residues released from the substrate 201 and/or its edge during or after operations performed with the system 200 (e.g., edge bevel removal). Prompt removal of the residues and radicals ensures that the residues do not contaminate the substrate surface and that the radicals do not damage any formed devices present on the substrate surface (e.g., on the frontside).

FIG. 2A illustrates an expanded, vertical cross-sectional view of the nozzle 230 used in the system 200, in some implementations. The nozzle 230 may include a first electrode 233 defined in approximately in the center of the nozzle 230. A dielectric material 238 may be disposed to surround the first electrode 233 so that a first channel 235 is defined between the first electrode 233 and the dielectric material 238. The first channel 235 may be connected to a first gas source (FIG. 2) through a first inlet 231 defined at a first end, and to a first opening 242 at a second end defined proximate to the top of the nozzle 230. The first channel 235 may be configured to receive a first gas from the first gas source through the first inlet 231. The first gas may be a reactant gas or a mixture of gases, such as a deposition or etching precursor and/or an inert gas. For deposition, the plasma chemistry may be selected to have deposition products for plasma enhanced chemical vapor deposition (PECVD) or plasma enhanced atomic layer deposition (PEALD). Example precursors for silicon dioxide deposition include silane and tetraethoxysilane (TEOS). Deposition gas for silicone nitride additionally may include nitrogen and ammonia as examples. An example precursor for tungsten deposition includes tungsten hexafluoride (WF₆). These examples are illustrative and do not exclude other chemistries selected for specific film compositions. In some etching implementations, the plasma chemistry may be selected to have volatile reaction products with the film to be etched. As examples, oxygen radicals can be specific to carbon (C) or carbon-based film, while fluorine (F) radicals may be selected against molybdenum (Mo) or tungsten (W) materials for removal. Appropriate reactants may be selected to target the metal or material to be etched. Carrier gases may be inert gases, for example, argon or helium. The reactant gas may be used to generate the plasma, and the inert gas may be used to carry plasma radicals of the reactant gas through the first opening 242. A second electrode 234 may be embedded within the dielectric material 238 and surround the first electrode 233. The dielectric material 238 may act as a barrier to metal surfaces so as to prevent arcing and metal contamination when RF power is applied.

The dielectric material 238 disposed within the nozzle 230 may further define a second channel 236 between the dielectric material 238 and an outer wall of the nozzle 239. The second channel 236 may be coupled to a second gas source (FIG. 2) through a second inlet 232 defined at a first end, to receive a second gas, and a second opening 243 is defined at a second end defined at the bottom of the nozzle 230. The second opening 243 may be defined adjacent to and surround the first opening 242. The second opening 243 may be a single opening or a plurality of openings that surround the first opening 242 (two are depicted in FIG. 2A). The second gas may be an inert gas, such as argon or helium. The second channel 236 may create a separate gas path for the second gas, and the second opening 243 in the top of the nozzle 230 may direct the second gas to flow up without perturbing the plasma radicals flowing through the first opening 242. The second gas exiting the second opening 243 may act as a shield for the plasma radicals mixed with the carrier gas exiting the first opening 242 by encircling the mixture of plasma radicals and the carrier gas.

Referring again to FIG. 2A, in some implementations, the second electrode 234 embedded in the dielectric material 238 may be oriented in parallel orientation to the first electrode 233 disposed approximately in the center of the nozzle 230. In some alternate implementations, the second electrode 234 embedded in the dielectric material 238 may be oriented perpendicular to the first electrode 233, at least in part. In yet alternate implementations, the second electrode 234 may be shaped to follow a contour of the dielectric material 238 and may be oriented so as to be parallel to the first electrode 233. Irrespective of the orientation, the second electrode 234 may be disposed at a pre-defined distance from the first electrode 233, wherein the pre-defined distance may be determined to enable generation of plasma of the first gas received in the first channel 235. In some implementations, the first electrode 233 may be made of metal. In some implementations, the first electrode 233 and the second electrode 234 may be made of same material. In some implementations, the first electrode 233 may be made of different material than the second electrode 234. The material used for the second electrode 234 may be chosen so as to withstand high temperatures. In some approaches, the material used for the second electrode 134 may be chosen to have a coefficient of thermal expansion (CTE) that matches the CTE of the dielectric material 238 in which the second electrode 234 is embedded. In some approaches, the first and the second electrodes 233, 234 may be made of any one of tungsten, molybdenum, iridium, rhenium, or platinum, and the dielectric material 238 may be made of any one of aluminum nitride, aluminum oxynitride, silicon nitride, aluminum oxide, or yttrium oxide. In some implementations, the dielectric material 238 and/or the first electrode 233 may be cooled using one or more cooling elements (not shown). In some cases, the cooling element may be disposed in a region that is proximate to the second electrode 234.

In some implementations, the first electrode 233 disposed proximate to the center of the nozzle 230 may be coupled to the aforementioned RF power source, and the second electrode 234 may be grounded via a match network. In some other implementations, the first electrode 233 may be grounded and the second electrode 234 may be coupled to the RF power source via a match network. In yet other implementations, the first electrode 233 and the second electrode 234 may be coupled to the RF power source via a match network, and neither the first electrode 133 nor the second electrode 134 may be grounded.

In some configurations, a differential voltage may be applied to the first electrode 233 and the second electrode 234. As an illustrative example, for an input voltage of 2 volts (V), the voltage applied to the first electrode will be +1 V and the voltage applied to the second electrode will be −1 V (i.e., each electrode may be provided with one half of the input voltage). In some instances, a differential drive (not shown) may be coupled to the RF power source and used to switch the RF power input between the two electrodes (first electrode 233, second electrode 234). In some implementations, the differential drive may be an isolation transformer with secondary windings used to provide the differential voltage.

In some implementations, the first gas may include a mixture of a reactant gas and a carrier gas. In some specific implementations, the first gas may include a mixture of a deposition precursor and carrier gas, or a mixture of an etchant gas and a carrier gas. Hence, in some cases, the reactant gas may be oxygen, and the carrier gas may be an inert gas such as argon. In some cases, the reactant gas may be oxygen, and the carrier gas may be another inert gas such as helium. It should be noted that the aforementioned examples of gases are provided as mere examples and should not be considered restrictive. Where the system 200 is used for edge bevel removal, depending on the type of films (i.e., residues) of the edge material that is being targeted for removal, the carrier gas may be any stable, inert gas such as argon or helium, and the etchant gas may be fluorine, chlorine, or some other halogen, or hydrogen.

The topology of the nozzle 230 may be defined so as to supply high density plasma radicals to the substrate 201 in order to achieve high precision etching or deposition. In some example implementations, the flow rate of the reactant gas in the first gas may be defined to be between about 100 standard cubic centimeters per minute (sccm) and about 300 sccm, and the flow rate for the carrier gas flow may be defined to be between about 1,000 sccm and about 30,000 sccm.

The topology of the nozzle 230 may provide an efficient and effective way of processing the substrate 201 using a simple process chamber that includes minimal hardware. The plasma can be generated remotely and provided to the edge or other portions of the substrate 201. In addition to the first and the second gas being applied to the substrate 201, a third gas may also be provided from a third channel defined adjacent to the nozzle 220. The third gas may act as a gas curtain pushing the first gas enveloped in the second gas away from the center of the substrate so as provide focused application of the plasma radicals, whether at the substrate edge or at a defined radius from the center. The simple design may allow the process chamber to be kept lightweight and small, enabling the process chamber to be stacked on other existing modules (e.g., loadlock), leaving no additional footprints.

In some implementations, there may be ‘n’ number of nozzles (where ‘n’ is an integer) within the nozzle housing 220 providing the plasma radicals simultaneously to cover a larger area of the substrate 201 or its edge. In some implementations, the nozzle housing may include 3 or 5 or 7 or 9 nozzles disposed proximate to one another. In some implementations, the ‘n’ nozzles may be disposed along an arc defined in the nozzle housing 220. The arc may be defined to match the curvature of the substrate edge. In some implementations, the ‘n’ nozzles may be disposed in a substantially linear fashion rather than an arc that matches the curvature of the substrate edge. In some cases the linear nozzles may be spread in a radial direction such that the nozzles may deposit or etch at different radial positions along the substrate. Although various implementations have been described herein with reference to the system 200 using a nozzle, the implementations are not limited to nozzle operation, and other non-nozzle tools or parts may also be engaged for processing the substrate 201.

FIG. 2B illustrates an example view of the plasma radicals with the shield gas directed toward an edge 201-e of the substrate 201, according to some implementations of the system 200 of FIG. 2. The shield gas may prevent the plasma radicals from dispersing or recombining with the surrounding air, enabling focused application of the plasma radicals to the substrate edge 201-e. In the illustrated example operation, as the substrate 201 rotates 212′ about an axis (e.g., the same z-axis that the chuck 210 may spin 212), different portions of the substrate edge 201-e may be become exposed to the plasma radicals. Alternatively or additionally, depending on the position (e.g., x, y and/or z) and/or configuration (e.g., angle) of the nozzle(s) 230, different portions of an inner portion 201-i of the substrate 201 may become exposed to the plasma radicals. In some operations, the configuration may be used to deposit a layer on one or more portions of the substrate 201 on the backside as it rotates 212′, e.g., on the inner portion 201-i or the substrate edge 201-e. In some other operations, etching may be performed instead on the same areas. The nozzle 230 may be angled toward or away from the center portion of the substrate 201. The illustrated example shows that the nozzle 230 is angled away, which may assist with removal of the edge material and prevention of radical accumulation in other parts of the backside of the substrate 201. For further assistance, in some implementations, a third gas received in a third channel 237 defined adjacent to the nozzle 230 may be supplied through a third opening below the surface of the substrate 201, as noted above. In some implementations, the third channel 237 may be within the nozzle housing 220. The third gas may be supplied with sufficient force to keep the plasma radicals directed toward and processing the substrate 201 and to sufficiently expose the substrate 201 to the plasma radicals.

FIG. 3 illustrates a simplified block diagram of another system 300 configured to provide a pressurized jet of plasma radicals toward a backside of a semiconductor substrate 301, according to some embodiments. Similar to the system 200 shown in FIG. 2, the system 300, in some embodiments, may include a single nozzle 330 that is at least partially housed within a nozzle housing 320 of an assembly 305 that may integrate other components 325 along with the nozzle housing 320. In some embodiments, the nozzle housing 320 can be extended to include more than one nozzle. In such cases, each of the multiple nozzles may be capable of either etching or depositing; e.g., a first nozzle may be used for depositing, and a second nozzle may be used for etching. The system 300 may be operated at atmospheric conditions. The system 300 incorporating the nozzle 330 allows for minimal hardware changes while significantly improving the deposition or etch rate with respect to the substrate 301.

In some embodiments, similar to the system 200 shown in FIG. 2, an RF power source may be coupled to the nozzle 330 so as to provide RF power to electrodes (e.g., a first electrode and a second electrode) that may be housed within the nozzle 330 or the nozzle housing 320. The RF power source and/or one or more gas sources (e.g., a first gas source and a second gas source) may be connected to the nozzle housing 320, the nozzle(s) 330, and/or components of the assembly 305 or components of the nozzle housing 320 (e.g., electrodes) via an electrical line and/or a gas line. In some implementations, the RF power source may be coupled to the nozzle 330 and configured to provide RF power to generate plasma of the first gas (e.g., in a first channel defined between the first electrode and the second electrode). The RF power may be used to generate radicals of plasma of the first gas in a first channel. The radicals may then be carried out of the first channel through a first opening (i.e., first outlet) defined at an opening of the nozzle 330.

In system 300, unlike in system 200, the substrate 301 is stationary (does not rotate) and may be supported by one or more supports structures (e.g., annular supports). Each annular support may be secured to a surface, such as the ground or another surface of a process chamber. The annular supports may be at least partially hollow, or be connected to other structures or lines (e.g., to provide air or suction). Various structures other than tubular may be used. In FIG. 3, two example annular supports 310a and 310b are partially shown to illustrate how the annular supports contact and hold the substrate 301. However, it is appreciated that more annular supports may be used, as shown in FIGS. 3A and 3B. In some cases, only one annular support may be used if the substrate 301 is partially supported by other structure (e.g., a shelf protruding from a sidewall of a process chamber). In some embodiments, the substrate 301 may be supported and held stationary by a carrier ring (e.g., tabs of a carrier ring).

In some embodiments, the nozzle housing 320 may be coupled to a stage 314 (or actuator) configured to move in multiple degrees of freedom. For example, the stage 314 may be an X-Y-Z stage that is capable of traversing in x, y and z directions, thereby moving the nozzle housing 320 and the nozzle 330 to a desired position in the (x, y, z) space. As an illustrative example, the nozzle housing 320 can be moved along an axis 316 underneath the substrate 301. The stage 314 may alternatively or additionally be an R-θ-Z stage capable of traversing based in the (r, θ, z) space, where the position of the nozzle 330 or nozzle housing 320 may be determined based on radius (r) and angle (θ) from a reference point, and height (z). As an illustrative example, the nozzle housing 320 can be rotated or revolved 317 around the center of the substrate 301 and underneath the substrate 301. For instance, the nozzle 330 can be pointed toward the backside the substrate 301 along an arc that has a substantial similar curvature as that of the edge of the substrate 301.

In some embodiments of the system 300, the RF power may be modulated so as to vary the emission of plasma radicals as the position of the nozzle changes position with respect to the substrate 301 (e.g., using stage 314), thereby creating a desired pattern of deposition or etching, e.g., at the backside of the substrate 301. Such modulation may be performed based on signals generated by a controller, logic, a differential drive, etc. that is coupled to the nozzle 330. The stage 314 may be provided signals to traverse underneath the substrate 301 according to the foregoing signals, while avoiding collision with supporting structures such as the annular supports 310.

In some implementations, the assembly 305 may further include a second housing 340 or other structure opposing the nozzle housing 320. In some implementations, the second housing 340 may be stationary. In some implementations, the second housing 340 may be movable, e.g., along the z-axis. A gap 335 may thereby be created between the nozzle housing 320 and the second housing 340 to accommodate and received a portion of the substrate 301, similar to that described with respect to FIG. 2.

In some implementations, the system 300 may include an exhaust (not shown) to promptly remove plasma radicals and residues released from the substrate 301 and/or its edge during or after operations performed with the system 300 (e.g., edge bevel removal). Prompt removal of the residues and radicals ensures that the residues do not contaminate the substrate surface and that the radicals do not damage any formed devices present on the substrate surface (e.g., on the frontside).

FIG. 3A illustrates an example cross-sectional view of the substrate 301 that may be processed using system 300. As discussed above, the substrate 301 may be stationary and supported by one or more annular supports. The one or more annular supports may be distributed substantially evenly about the perimeter of the substrate 301. FIG. 3A illustrates three annular supports that are not co-planar with one another.

For example, as illustrated in the top-down view of FIG. 3A's substrate 301 in FIG. 3B, three annular supports 310a-310c may form a tripod or similar balanced support. It will be appreciated that such annular supports 310a-310c need not be disposed at the edge of the substrate 301. One or more of the annular supports 310a-310c may instead be disposed away from the edge. In some implementations, at least some of the annular supports 310a-310c may possess a vacuum-based or other mechanism to assist with holding the substrate 301. In some implementations, one or more of the annular supports 310a-310c may be replaced by other types of structures, such as a tab of a carrier ring.

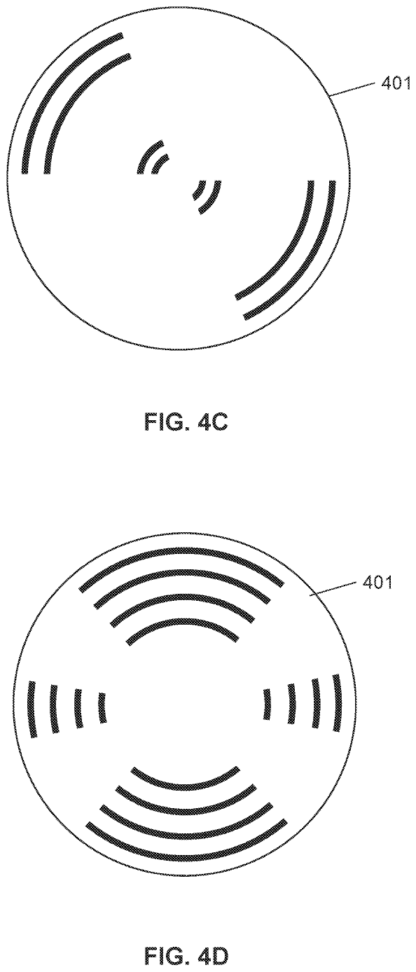

FIGS. 4A-4D are illustrative example patterns of deposition or etch using an APPJ-based system 200. The deposition patterns may be effectuated by spinning a substrate or wafer at a defined rate of rotation (e.g., 60-120 rotations per minute), and modulating the RF power to plasma jets (e.g., nozzle(s) 230 or 330) to cause deposition or etching at desired locations (e.g., radial position, angularly defined areas or slices of the substrate). Deposition or etching may form arcs, such as arcs 402a-402d, using FIG. 4A as an illustrative example.

In alternate scenarios, the example deposition/etch patterns may alternatively be formed using an APPJ-based system 300. For example, rotation of the nozzle housing 320 about an axis of a stage using R-θ-Z capabilities may form the deposition/etch arcs (e.g., 402a-402d) as seen in the example patterns, and translation of the nozzle housing 320 using X-Y-Z capabilities, or tilting of the nozzle 330, may allow deposition/etch of arcs that vary in radial position (e.g., 402a versus 402b) In some implementations, the rate of rotation may be constant throughout the deposition or etch process. RF power to plasma jets (e.g., nozzle(s) 230 or 330) may be modulated at a consistent pattern (e.g., high/low or on/off) corresponding the constant rate of rotation to cause emissions of plasma radicals toward the backside of the substrate. Advantageously, modulation of RF power while rotating the substrate is an efficient way to deposit or etch in a consistent pattern, as modulation of the RF power can be done quickly, and the modulation of the RF power and the rotation of the substrate can be synchronized. In the example use case of film deposition, controlling the film thickness is also simplified by increasing the duration the substrate is rotated. Further, using the movable nozzle housing as discussed with respect to FIGS. 2 and 3, the radial position of deposition may be easily controlled.

In some implementations, however, the rate of rotation may vary or may be changed depending on processing conditions, user commands, or radial or angular position of the plasma jet. Varying the rate of rotation during a single substrate rotation may allow material to be deposited thicker in some angular positions (where the rotation rate is slower) than in other angular positions.

FIG. 4A illustrates one example pattern of deposition that may be created by APPJ-based system 200 (or 300). Based on the rotation of the substrate 401 and the RF modulation of the plasma jet, two general types of areas may be created, e.g., on the backside of the substrate 401. Deposition arcs 402a-402d and 404a-404d may create areas where layers are deposited, whereas empty portions 406a and 406b may not be processed via deposition. Deposition arcs may correspond to when RF power is applied to the plasma jet to emit plasma radicals, and empty portions 406a and 406b may correspond to when RF power is not applied. In this example, deposition arcs alternate with empty portions, in accordance with the RF modulation (e.g., high/low or on/off).

The deposited layers on the backside of the substrate 401 may introduce internal stress that, e.g., counteracts pre-existing internal stress (caused by, e.g., one or more frontside layers), thereby compensating for bow existing in the substrate 401, including an asymmetrical or non-uniform bowing, such as a saddle-shaped bow. More specifically, varying the thickness of the resultant backside layer as a function of position (e.g., based on the pre-existing bow caused by, e.g., frontside deposition or inadvertent or unintentional backside deposition), thereby varying the internal stress of the backside layer as a function of position, can compensate for the pre-existing bow of the substrate. The internal stress (e.g., in magnitude and/or direction) of the resulting backside layer can vary as a function of position; even a uniform thickness layer may have different values of internal stress at different positions on the substrate. Hence, the bow compensation effect of the backside layer may vary as a function of position, where the bow compensation effect may be a function of (i) the backside layer thickness, and (ii) the backside layer internal stress, which is an intrinsic property of the material that forms the backside layer.

Etching in the same pattern as shown in FIG. 4A may be performed similarly, using RF modulation of a plasma jet. As an example, etching may remove unintended deposits on portions of the backside of a substrate. In some scenarios, a frontside deposition process may cause some material to unintentionally deposit on the backside of the substrate. Such backside deposition may not be desired and should be removed before further processing. With information about the location of the backside deposited material, a plasma jet may be selectively directed at regions (e.g., along one or more of the arcs shown in FIGS. 4A-4D) where the backside deposited material has occurred to thereby etch away that material.

FIG. 4B shows another example pattern of deposition/etch that may be created by APPJ-based system 200 (or 300). In this example pattern, deposition or etching may occur near the edges of the substrate 401, e.g., at arcs 412a, 412b. In this example pattern, deposition or etching may occur in different sectors of the substrate 401, more internally toward the center of the substrate 401, e.g., at arcs 414a-414d.

FIG. 4C shows another example pattern of deposition/etch that may be created by APPJ-based system 200 (or 300). Arcs may be present near the edge of the substrate 401 and also more internally closer to the center of the substrate 401.

FIG. 4D shows another example pattern of deposition/etch that may be created by APPJ-based system 200 (or 300). Some arcs may be wider, while some arcs are narrower.

The example patterns of FIGS. 4A-4D are purely illustrative and merely serves to depict the effect of RF modulation with the plasma jet processing a substrate that is secured while in rotation as discussed with respect to the systems 200, or a substrate that is secured while stationary as discussed with respect to the system 300. Myriad other patterns may be formed (e.g., on the backside of the substrate) as desired according to the bowing caused by components or other processing that has occurred (e.g., on the frontside of the substrate).

### Methods

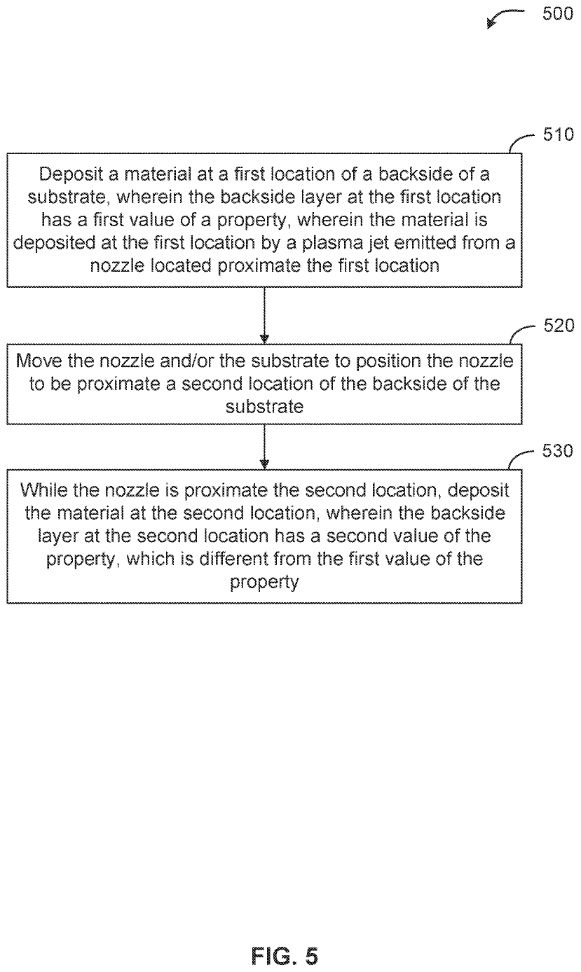

FIG. 5 is a flow diagram illustrating a method 500 of depositing a backside layer on a backside of a substrate, according to some embodiments. The substrate may have a frontside, the frontside having electronic device features fabricated thereon. One or more of the functionalities of the method 500 may be performed by or caused by a computerized apparatus or system. Structure for performing the functionality illustrated in one or more of the blocks shown in FIG. 5 may include hardware and/or software components of such computerized apparatus or system, or computing device, such as, for example, a controller apparatus, a computerized system, or a computer-readable apparatus including a storage medium storing computer-readable and/or computer-executable instructions that are configured to, when executed by a processor apparatus, cause the at least one processor apparatus or a computerized apparatus to perform the operations. A controller may be one example of the computerized apparatus or system or a component thereof. A process chamber may be another example of the computerized apparatus or system.

It should also be noted that the operations of the method 500 may be performed in any suitable order, not necessarily the order depicted in FIG. 5. Further, the method 500 may include additional or fewer operations than those depicted in FIG. 5 to deposit the backside layer.

At block 510, the method 500 may include depositing a material at a first location of the backside of the substrate. The portion of the substrate where arcs 402a-402d may be an example of the first location. In some embodiments, the backside layer at the first location has a first value of a property, wherein the material is deposited at the first location by a plasma jet emitted from a nozzle located proximate the first location. The nozzle may be an example of the nozzle 220 or 320. In some implementations, the nozzle may be one of a plurality of nozzles, which may be arranged in an arc, which may conform generally to a curvature of an edge of the substrate. In some implementations, plurality of nozzles may be arranged in a linear fashion, e.g., along a radial direction such that the multiple nozzles may deposit layers (or etch materials) at different radial positions along the substrate.

In some embodiments, the depositing is performed using an atmospheric pressure plasma jet (APPJ)-based system such as system 200 or 300 as discussed with respect to FIG. 2 or 3. The deposited material may be a product of plasma generated using the nozzle, as discussed with respect to FIG. 2 or FIG. 3. In some implementations, the operation of the system and/or the nozzle may include emission of a plasma jet associated with the nozzle onto the backside of the substrate at about atmospheric pressure. In some implementations, the operation may include emission at about 0.5 to 1.5 times atmospheric pressure. Based on various implementations, the deposited material may comprise one or more layers of the backside layer. The number of the one or more layers may be predetermined. This information may influence, e.g., the number of rotations to process at least the first location on the backside of the substrate.

In some embodiments, the property may include a bow compensation effect of the backside layer, e.g., a distance between the edge or center of the substrate and the average midplane of the substrate (e.g., midplane 120′ of FIG. 1C), which may be smaller compared to the distance before the bow compensation. In some embodiments, the property may include internal stress of the material in the backside layer. In some embodiments, the property may include a thickness of the backside layer.

At block 520, the method 500 may include moving the nozzle and/or the substrate to position the nozzle to be proximate a second location of the backside of the substrate. In some embodiments, the substrate is moved via rotation, where the substrate is secured and held by a chuck. Hence, in some cases, the empty portion 406a may be an example of the second location. In some cases, arcs 404a-404d may be an example of the second location. In some implementations, a vacuum chuck may hold the substrate at the center, and cause the substrate to rotate at a defined rate of rotation (e.g., 60-120 rotations per minute). The rotation may cause the second location of the backside of the substrate to be positioned over the nozzle, albeit for a moment. In some implementations, the nozzle may face the first portion and the second portion in alternating fashion (e.g., from 402a to 406 a). As another example, the chuck may translate (e.g., in the x, y and/or z-axis) such that the backside of the substrate is positioned over the nozzle at a different location of the backside. For instance, the substrate may be moved such that the nozzle now faces 402b from its prior position of facing 402a. In some implementations, the nozzle housing of the nozzle (such as nozzle housing 220 or 320) may be moved toward or away from the substrate (translated or rotated). In some implementations, both the substrate and the nozzle may move, e.g., toward or away from each other, or in the same direction at different distances.

At block 530, the method 500 may include, while the nozzle is proximate the second location, depositing the material at the second location, wherein the backside layer at the second location has a second value of the property, which is different from the first value of the property. In some embodiments, deposition may occur at different amounts between the first and second locations. For example, if the first location proximate to the nozzle is 402a and the subsequent second location proximate to the nozzle is 402b, then there may be a different amount of deposition of the material needed to reduce the bow because different amounts of internal stress may be present on the corresponding locations on the frontside of the substrate. As another example, if the first location is 402a and the second location is 406a, then the second location may require much less deposition for the bow compensation effect.

The surface modification described above is not limited to deposition of film. In some implementations, the foregoing method 500 may be adapted for etching rather than deposition. That is, an etchant may be directed from the nozzle toward the substrate. Etching may bring about a bow compensation effect by removing unintended (or intended) deposits (e.g., a pre-existing film) on portions of the backside of a substrate, providing spatially varying stress relief.

In further alternative implementations, rather than emission of a plasma jet at the nozzle, a laser may be used instead, wherein the etch may involve ablation or true laser etch with laser excitation in a chemical ambient, or laser deposition with excitation in a chemical ambient.

### Apparatus—Computational and Controller Embodiments

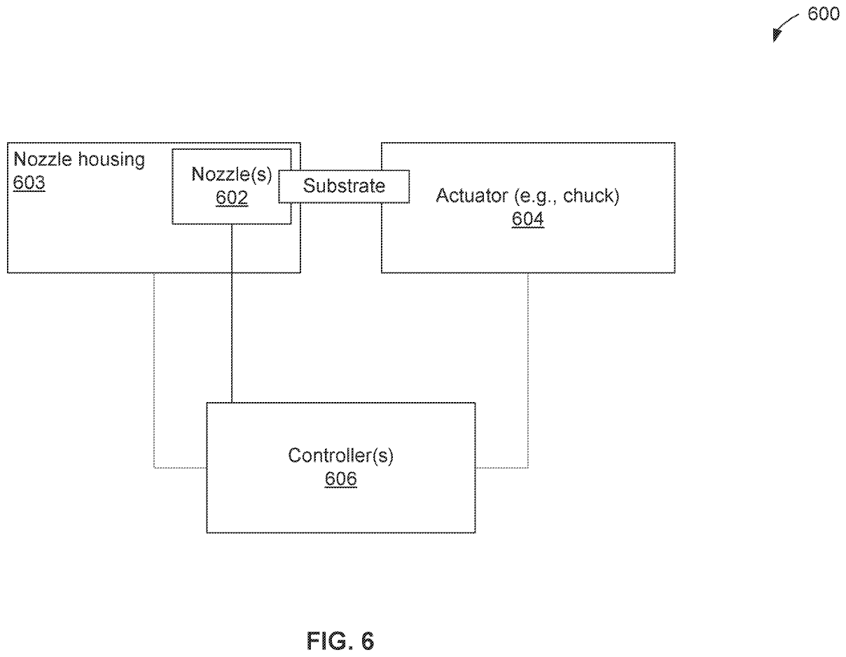

FIG. 6 illustrates a simplified block diagram of an APPJ-based system or apparatus 600 as described herein, which may include the a nozzle (or a plurality of nozzles) 602, actuator (e.g., chuck) 604, and a controller 606 (or a plurality of controllers) coupled to the nozzle(s), nozzle housing, and/or the actuator. Such apparatus may be configured to implement the foregoing method 500 using one or more of the aforementioned components 602-606. In some embodiments, operation of the apparatus may include emission of the plasma jet onto the backside of a substrate at about 0.5 to 1.5 times atmospheric pressure (e.g., at about atmospheric pressure).

In some example embodiments, the nozzle(s) 602 may be at least partially housed by a nozzle housing 603, and may be configured to direct a plasma jet onto the backside of the substrate and thereby deposit a material on the backside of the substrate and form a backside layer comprising the material; the actuator 604 may be configured to adjustably position the backside of the substrate with respect to the nozzle(s) 602 during deposition of the backside layer; and the controller(s) 606 may be configured to cause the plasma jet to deposit the material on the backside of the substrate in a manner such that the formed backside layer has different properties varying at different locations of the backside layer (which may, for example, result in example deposition/etch patterns shown in FIGS. 4A-4D or other types of patterns).

In some implementations, the nozzle(s) 602 may be housed in a nozzle housing, which may include an inlet line configured to deliver gas and/or plasma from a source to an outlet of the nozzle(s) 602. An axis of the nozzle(s) 602 may be at an angle relative to a plane parallel to the substrate, the angle being adjustable between orthogonal to non-orthogonal (angled). In various configurations, the controller(s) 606 may be further configured to adjust one or more process conditions during an operation of the computerized apparatus. The process conditions may include: a rotation rate of the substrate using the actuator 604; a position and/or an angle associated with the nozzle(s) 602, a plasma power associated with the plasma jet of the nozzle(s) 602, a plasma frequency associated with the plasma jet of the nozzle(s) 602, a residence time of the plasma jet at a location on the substrate, a gas flow rate, a gas composition, a gas pressure, or any combination thereof. In some cases, the controller(s) 606 may be configured to adjust plasma power during a single rotation of the actuator 604 and the substrate. In some cases, the controller(s) 606 may be configured to adjust plasma power (e.g., high/low or on/off) repeatedly over numerous rotations of the actuator 604 and the substrate.

In some implementations, the actuator 604 may be configured to, during the deposition of the material, rotate the substrate (as discussed with respect to the FIG. 2 system 200). The actuator 604 may be configured to cause the substrate to translate relative to the substrate along a plane parallel to the substrate, or along a plane orthogonal to the plane parallel to the substrate (e.g., z-axis), or cause the substrate to move radially relative to the substrate. Depending on the application, the rotation speed of the substrate may be 60-120 rotations per minute. In one example, the rate of rotation may be about 100 rotations per minute. The actuator 604 may also be configured to provide rasterized deposition of the material. The actuator 604 may also be configured to maintain a gap between the substrate and an outlet of the nozzle(s) 602 during the deposition of the material, and wherein the gap is between about 100 and 1000 micrometers (0.1-1 mm).

In various implementations of the foregoing method 500, the manner of deposition of the material may include deposition of the material at the different locations of the backside layer so as to compensate for a bow of the substrate. The deposition of the material at the different locations of the backside may include deposition at different angular regions and/or different radial regions of the substrate.

In some operations, controller(s) 606 may be configured to, e.g., during a second operation, direct an etchant from the nozzle(s) 602 toward the substrate.

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

In some implementations, a “controller” (e.g., 190) is part of a system containing a various types of sensors as described herein. Such systems include a fabrication tool with a camera sensor. Such systems can include semiconductor processing equipment, including a processing tool or tools, chamber or chambers, a platform or platforms for processing, and/or specific processing components (a substrate pedestal, a gas flow system, etc.). These systems may be integrated with electronics for controlling their operation before, during, and after processing of a semiconductor substrate or wafer. The controller may be implemented with or coupled to analysis logic as described above. A controller may be implemented as logic such as electronics having one or more integrated circuits, memory devices, and/or software that receive instructions, issue instructions, control operation, and/or enable sensing operations.

The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, substrate transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor substrate or to a system. The operational parameters may, in some embodiments, be part of a recipe defined by process engineers to accomplish one or more processing steps during the processing of one or more layers, materials, metals, oxides, silicon, silicon dioxide, surfaces, circuits, and/or dies of a substrate.

A controller may be configured to control or cause control of various components or subparts of the system or systems. The controller, depending on the processing requirements and/or the type of system, may be programmed to control any of the processes that may be used by a fabrication tool during a fabrication operation, including adjusting or maintaining the delivery of processing gases, temperature settings (e.g., heating and/or cooling) including substrate temperature and chamber wall temperature, pressure settings including vacuum settings, plasma settings, RF matching circuit settings, and substrate positional and operation settings, including substrate transfers into and out of a fabrication tool and/or load lock. Process gas parameters include the process gas composition, flow rate, temperature, and/or pressure. Of particular relevance to the disclosed embodiments, controller parameters may relate to plasma generator power, pulse rate, and/or RF frequency.

Process parameters under the control of a controller may be provided in the form of a recipe and may be entered utilizing a user interface. Signals for monitoring the process may be provided by analog and/or digital input connections of the system controller. The signals for controlling the process are output on the analog and digital output connections of the deposition apparatus.

In one example, the instructions for bringing about ignition or maintenance of a plasma are provided in the form of a process recipe. Relevant process recipes may be sequentially arranged, so that at least some instructions for the process can be executed concurrently. In some implementations, instructions for setting one or more plasma parameters may be included in a recipe preceding a plasma ignition process. For example, a first recipe may include instructions for a first time delay, instructions for setting a flow rate of an inert gas (e.g., helium) and/or a reactant gas, and instructions for setting a plasma generator to a first power set point. A second, subsequent recipe may include instructions for a second time delay and instructions for enabling the plasma generator to supply power under a defined set of parameters. A third recipe may include instructions for a third time delay and instructions for disabling the plasma generator. It will be appreciated that these recipes may be further subdivided and/or iterated in any suitable way within the scope of the present disclosure. In some deposition processes, a duration of a plasma strike may correspond to a duration of a few seconds, such as from about 3 seconds to about 15 seconds, or may involve longer durations, such as durations of up to about 30 seconds, for example. In certain implementations described herein, much shorter plasma strikes may be applied during a processing cycle. Such plasma strike durations may be on the order of less than about 50 milliseconds, with about 25 milliseconds being utilized in a specific example. As explained, plasma may be pulsed.

In some embodiments, a controller is configured to control and/or manage the operations of a RF signal generator. In certain implementations, a controller is configured to determine upper and/or lower thresholds for RF signal power to be delivered to a fabrication tool, determining actual (such as real-time) levels of RF signal power delivered to integrated circuit fabrication chamber, RF signal power activation/deactivation times, RF signal modulation duration (for, e.g., high/low or on/off states), duty cycle, operating frequency, and so forth.

As further examples, a controller may be configured to control the timing of various operations, mixing of gases, the pressure in a fabrication tool, the temperature in a fabrication tool, the temperature of a substrate or pedestal, the position of a pedestal, chuck and/or susceptor, and a number of cycles performed on one or more substrates.

A controller may comprise one or more programs or routines for controlling designed subsystems associated with a fabrication tool. Examples of such programs or routines include a substrate positioning program, a process gas control program, a pressure control program, a heater control program, and a plasma control program. A substrate positioning program may include program code for process tool components that are used to load the substrate onto a pedestal and to control the spacing between the substrate and other parts of a fabrication tool. A positioning program may include instructions for moving substrates in and out of the reaction chamber to deposit films on substrates and clean the chamber.

A process gas control program may include code for controlling gas composition and flow rates and for flowing gas into one or more process stations prior to deposition to bring about stabilization of the pressure in the process station. In some implementations, the process gas control program includes instructions for introducing gases during formation of a film on a substrate in the reaction chamber. This may include introducing gases for a different number of cycles for one or more substrates within a batch of substrates. A pressure control program may include code for controlling the pressure in the process station by regulating, for example, a throttle valve in the exhaust system of the process station, a gas flow into the process station, etc. The pressure control program may include instructions for maintaining the same pressure during the deposition of differing numbers of cycles on one or more substrates during the processing of the batch.

A heater control program may include code for controlling the current to a heating unit that is used to heat the substrate. Alternatively, the heater control program may control delivery of a heat transfer gas (such as helium) to the substrate.

In some implementations, there may be a user interface associated with a controller. The user interface may include a display screen, graphical software displays of the apparatus and/or process conditions, and user input devices such as pointing devices, keyboards, touch screens, microphones, etc.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the substrate processing. The computer may enable remote access to the system to monitor current progress of processing operations, examine a history of past processing operations, examine trends or performance metrics from a plurality of processing operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the processing and/or manufacturing of semiconductor wafers.

The system software may be organized in many different ways that may have different architectures. For example, various chamber component subroutines or control objects may be written to control operation of the chamber components necessary to carry out the deposition processes (and other processes, in some cases) in accordance with the disclosed embodiments.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Certain features that are described in this specification in the context of separate implementations also can be implemented in combination in a single implementation. Conversely, various features that are described in the context of a single implementation also can be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

1. An apparatus for surface modification of a backside of a substrate, the substrate having a frontside, the frontside having electronic device features fabricated thereon, the apparatus comprising:
a nozzle configured to direct a plasma jet onto the backside of the substrate and thereby deposit a material on the backside of the substrate and form a backside layer comprising the material;
an actuator configured to adjustably position the backside of the substrate with respect to the nozzle during deposition of the material; and
a controller configured to cause the plasma jet to deposit the material on the backside of the substrate in a manner such that the formed backside layer has different properties varying at different locations of the backside layer.

2. The apparatus of claim 1, wherein the manner of deposition of the material on the backside comprises deposition of the material at the different locations of the backside so as to compensate for a bow of the substrate.

3. The apparatus of claim 2, wherein the deposition of the material at the different locations of the backside comprises deposition at different angularly defined regions of the backside of the substrate, different radially defined regions of the backside of the substrate.

4. The apparatus of claim 1, wherein the properties comprise a bow compensation effect of the backside layer, a thickness of the backside layer, an internal stress of the material on the backside layer, or a combination thereof.

5. The apparatus of claim 1, wherein the controller is further configured to adjust one or more process conditions, the one or more process conditions comprising:
a rotation rate of the substrate using the actuator;
a position and/or an angle associated with the nozzle;
a plasma power associated with the plasma jet;
a plasma frequency associated with the plasma jet;
a residence time of the plasma jet at a location on the substrate;
a gas flow rate;
a gas composition;
a gas pressure; or
any combination thereof.

6. The apparatus of claim 1, wherein the actuator is further configured to, during the deposition of the material, rotate the substrate.

7. The apparatus of claim 6, wherein a speed of the rotation of the substrate is about 60 to 120 rotations per minute.

8. The apparatus of claim 6, wherein the controller is further configured to adjust plasma power over course of a single rotation of the actuator and the substrate.

9. The apparatus of claim 1, wherein the actuator is further configured to cause the substrate to translate relative to the substrate along a plane parallel to the nozzle.

10. The apparatus of claim 9, wherein the actuator is further configured to cause the substrate to move radially relative to the nozzle.

11. The apparatus of claim 9, wherein the actuator is further configured to provide rasterized deposition of the material.

12. The apparatus of claim 1, wherein an axis of the nozzle is at an angle relative to a plane parallel to the substrate, the angle being adjustable between orthogonal to non-orthogonal.

13. The apparatus of claim 1, wherein the apparatus further comprises an inlet line configured to deliver gas and/or plasma from a source to an outlet of the nozzle.

14. The apparatus of claim 1, wherein the actuator is configured to maintain a gap between the substrate and an outlet of the nozzle during the deposition of the material, and wherein the gap is between about 100 and 1000 micrometers.

15. The apparatus of claim 1, wherein the deposition of the material comprises emission of the plasma jet onto the backside of the substrate at about 0.5 to 1.5 times atmospheric pressure.

16. The apparatus of claim 1, wherein the controller is configured to, during a first operation, cause the plasma jet to deposit the material on the backside of the substrate, and during a second operation, direct an etchant from the nozzle toward the substrate.

17. A method of depositing a backside layer on a backside of a substrate, the substrate having a frontside, the frontside having electronic device features fabricated thereon, the method comprising:
depositing a material at a first location of the backside of the substrate, wherein the backside layer comprises the material, wherein the backside layer at the first location has a first value of a property, wherein the material is deposited at the first location of the backside of the substrate by a plasma jet emitted from a nozzle located proximate the first location;
moving the nozzle and/or the substrate to position the nozzle to be proximate a second location of the backside of the substrate; and
while the nozzle is proximate the second location, depositing the material at the second location of the backside of the substrate, wherein the backside layer at the second location has a second value of the property, which is different from the first value of the property.

18. The method of claim 17, wherein the property is a bow compensation effect of the backside layer, a thickness of the backside layer, an internal stress of the material on the backside layer, or a combination thereof.

19. The method of claim 17, wherein:
the first location comprises a first angularly defined region of the backside of the substrate, a first radially defined position of the backside of the substrate, or a combination thereof; and
the second location comprises a second angularly defined region of the backside of the substrate which is different from the first angularly defined region, a second radially defined position of the backside of the substrate which is different from the first radially defined region, or a combination thereof.

20. The method of claim 17, further comprising rotating the substrate;
wherein:
the material is deposited at the first location by the plasma jet emitted from the nozzle while the substrate is being rotated; and
the material is deposited at the second location by the plasma jet emitted from the nozzle while the substrate is being rotated.
